(19) United States
(12) Patent Application Publication
(10) Pub. No.: US 2009/0224661 A1
(43) Pub. Date: Sep. 10, 2009

(54) Organic Light Emitting Device

(75) Inventor: Takahiro Nakayama, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/372,932

(22) Filed: Feb. 18, 2009

(30) Foreign Application Priority Data
Mar. 7, 2008 (JP) 2008-057334

(51) Int. Cl. H01J 1/62

(52) U.S. Cl. 313/504

(57) ABSTRACT

The present invention provides an organic light emitting device which has resonators for respective three colors of a red range, a green range, and a blue range. In one aspect, a total resonator length of the resonator of the red range is m times larger than a wavelength of the red range, and a total resonator length of the resonator of the blue range is (m+1) times larger than a wavelength of the blue range. In another aspect, a total resonator length of the resonator of the red range is m times larger than a wavelength of the red range, and a total resonator length of the resonator having the green range is (m+1) times larger than a wavelength of the green range, and a total resonator length of the resonator having the blue range is (m+2) times larger than a wavelength of the blue range.

### CROSS-REFERENCE TO RELATED APPLICATION

The present application claims priority from Japanese application JP 2008-057334 filed on Mar. 7, 2008, the content of which is hereby incorporated by reference into this application.

### BACKGROUND OF THE INVENTION

1. Field of the Invention

The present invention relates to an organic light emitting device in which a resonator structure having a laminated-layer structure for each of three primary colors (red: R, green: G, blue: B) for a full-color display is optimized.

2. Description of the Related Art

In JP 08-213174 A, there is disclosed that a translucent reflection mirror is disposed on a front of a light emitting surface of an organic light emitting device to obtain a resonator (micro-resonator) having a round-trip optical path length which becomes natural number times larger than a desired light emission wavelength, whereby emission spectra are changed into a monochromatic state and a light emission peak intensity is enhanced at the same time. Note that, physical properties relating to a resonator structure are described in detail in T. Nakayama, “Organic luminescent devices with a microcavity structure,” included in “Organic electroluminescent materials and devices,” edited by S. Miyata, published by Gorden & Breach Science Publisher (1997).

Further, JP 2005-116516 A describes that, in a full-color display device using the organic light emitting elements for three primary colors of red: R, green: G, and blue: B (hereinafter, referred to as R, G, and B), in order to optimize resonator structures of the organic light emitting elements for each of R, G, and B, the organic light emitting elements each have a different thickness in accordance with light emission wavelengths thereof.

In a manufacturing process of the organic light emitting elements for each of R, G, and B, it is a simple manufacturing process to form layers which are common among the organic light emitting devices for R, G, and B, such as an electron transport layer, a hole transport layer, and a transparent electrode, in one process preferably without using masks, compared with a vapor deposition of the layers using the masks in separate steps for R, G, and B. It is advantageous in terms of cost if the manufacturing process is simplified. At the same time, it is necessary to optimize thicknesses of the layers to provide excellent light emission characteristics.

However, in order to form the organic light emitting elements for R, G, and B and simultaneously make resonator lengths based on thicknesses thereof correspond to colors of light emitted therefrom, the resonator lengths are necessary to be changed in proportion to wavelengths of R, G, and B, because a relationship of the wavelengths in light emitting regions of R, G, and B is represented as R>G>B. Therefore, it is necessary to change a thickness of each layer without optimizing charge injection into the organic light emitting elements or to make the manufacturing process complicated and change a thickness of an underlying layer such as the transparent electrode, which causes a reduction in device characteristic and an increase in manufacturing cost.

### SUMMARY OF THE INVENTION

The present invention has an object to provide an organic light emitting device in which a resonator structure is optimized without changing a thickness of a light emitting layer of red (R), green (G), or blue (B).

According to an aspect of the present invention, there is provided an organic light emitting device including: resonators for respective three colors of a red range, a green range, and a blue range; and a plurality of layers. When an optical path length which is a sum of values each obtained by multiplying a refractive index nᵢ of each layer i of the plurality of layers by a thickness dᵢ thereof and doubling a resultant is denoted by Σ2nᵢdᵢ, a length obtained by adding an amount of a phase shift owing to an interface reflection and an offset length is denoted by Δ, a natural number is denoted by m, a resonance wavelength is denoted by λ, and a total resonator length is denoted by L, L=Σ2nᵢdᵢ+Δ=mλ is satisfied. In the resonator having the red range that emits light, a total resonator length thereof is m times larger than a wavelength λ_{R} of the red range, and in the resonator having the blue range that emits light, a total resonator length thereof is (m+1) times larger than a wavelength λ_{B} of the blue range.

Further, in the aspect of the present invention, a light emission of the red range and a light emission of the blue range may simultaneously satisfy a resonance condition in which each of the light emissions of the colors is in phase.

When the resonator length of the resonator having the red range that emits light is denoted by mλ_{R} and the resonator length of the resonator having the blue range that emits light is denoted by (m+1) λ_{B}, the thicknesses of the resonator having the red range that emits light and the resonator having the blue range that emits light are made equal to each other, whereby resonance conditions of the respective colors of the light emissions can be simultaneously satisfied.

Further, in the aspect of the present invention, in the resonator having the green range that emits light, the total resonator length L thereof may be one of increased and decreased, and a resonance condition corresponding to one of the resonator having the blue range and the resonator having the red range may be applied to the resonator having the green range to be used.

In this case, m is natural number, λ_{R} is a resonance wavelength of the resonator for red (length of a wavelength of red light), λ_{G} is a resonance wavelength of the resonator for green (length of a wavelength of green light), and λ_{B} is a resonance wavelength of the resonator for blue (length of a wavelength of blue light).

Further, according to another aspect of the present invention, there is provided an organic light emitting device including: resonators for respective three colors of a red range, a green range, and a blue range; and a plurality of layers. When an optical path length which is a sum of values each obtained by multiplying a refractive index nᵢ of each layer i of the plurality of layers of the organic light emitting device by a thickness dᵢ thereof and doubling a resultant is denoted by Σ2nᵢdᵢ, a length obtained by adding an amount of a phase shift owing to an interface reflection and an offset length is denoted by Δ, a natural number is denoted by m, a resonance wavelength is denoted by λ, and a total resonator length is denoted by L, L=Σ2nᵢdᵢ+Δ=mλ is satisfied. In the resonator having the red range that emits light, a total resonator length thereof is m times larger than a wavelength λ_{R} of the red range, in the resonator having the green range that emits light, a total resonator length thereof is (m+1) times larger than a wavelength λ_{G} of the green range, and in the resonator having the blue range that emits light, a total resonator length thereof is (m+2) times larger than a wavelength λ_{B} of the blue range.

Further, in the another aspect of the present invention, a light emission of the red range, a light emission of the green range, and a light emission of the blue range may simultaneously satisfy a resonance condition.

When the resonator length of the resonator having the red range that emits light is denoted by mλ_{R}, the resonator length of the resonator having the green range that emits light is denoted by (m+1)λ_{G}, and the resonator length of the resonator having the blue range that emits light is denoted by (m+²)λ_{B}, the thicknesses of those resonators are made equal to each other, whereby resonance conditions of the respective colors of the light emissions can be simultaneously satisfied.

According to the present invention, a reduction in device characteristic and an increase in manufacturing cost, which have been caused by changing a thickness of a light emitting layer correspondingly to a resonator length of the organic light emitting device for each R, G, or B, can be reduced. The organic light emitting device of the present invention is suitable for display and illumination, in particular, a backlight of a liquid crystal display device.

### BRIEF DESCRIPTION OF THE DRAWINGS

In the accompanying drawings:

FIG. 1A is a schematic view of an organic light emitting device including resonators that emit red, green, and blue light according to an embodiment of the present invention;

FIG. 1B is a schematic view of the organic light emitting device including the resonators that emit red, green, and blue light according to the embodiment of the present invention;

FIG. 2 is an explanatory view of light propagation and interference generation in the organic light emitting device;

FIG. 3 is a relationship diagram between a total resonator length L and a resonance wavelength λ;

FIG. 4 is a schematic view of the organic light emitting device for determining resonance characteristics;

FIG. 5 is a graph illustrating a relationship among a thickness d, an optical path length 2nd, and a resonance peak wavelength λ;

FIG. 6 is a structural view of a full-color display panel, in which R, G, B pixels are arranged;

FIG. 7 is another structural view of the full-color display panel, in which the R, G, B pixels are arranged;

FIG. 8A is a graph illustrating a wavelength characteristic of a resonator structure illustrated in FIG. 7;

FIG. 8B is a graph illustrating a wavelength characteristic of an example of a green light emission;

FIG. 8C is a graph illustrating a wavelength characteristic of a green light emission through the resonator structure;

FIG. 9A is a graph illustrating the wavelength characteristic of the resonator structure illustrated in FIG. 7;

FIG. 9B is a graph illustrating a wavelength characteristic of another example of the green light emission; and

FIG. 9C is a graph illustrating a wavelength characteristic of the green light emission through the resonator structure.

### DETAILED DESCRIPTION OF THE INVENTION

Hereinafter, with reference to the drawings, a best mode of the present invention is described in detail.

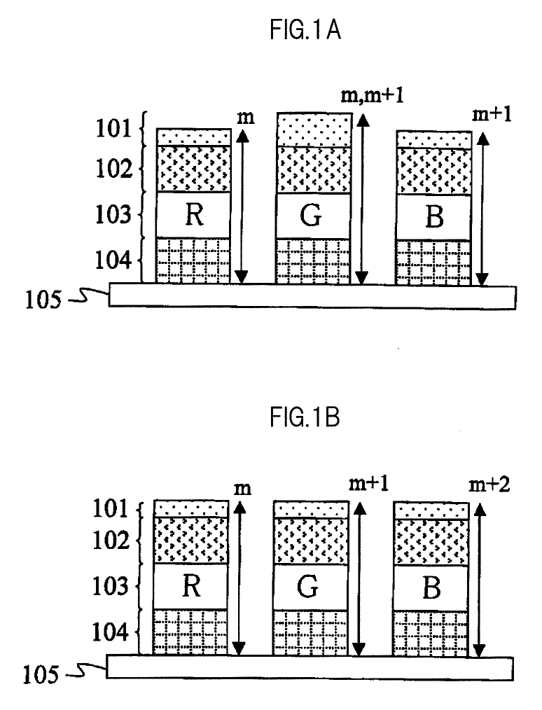

FIGS. 1A and 1B are schematic views of an organic light emitting device including resonators for red (R), green (G), and blue (B) according to an embodiment of the present invention. FIG. 1A is the schematic view of the organic light emitting device in which a resonator length mλ_{R} of the resonator having a red range that emits light and a resonator length (m+1)λ_{B} of the resonator having a blue range that emits light are equal to each other, and a resonator length (m+1)λ_{G} of the resonator having a green range that emits light is different therefrom. FIG. 1B is the schematic view of the organic light emitting device in which a resonator length mλ_{R} of the resonator having the red range, a resonator length (m+1)λ_{G} of the resonator having the green range, and a resonator length (m+2)λ_{B} of the resonator having the blue range are equal to one another.

In FIGS. 1A and 1B, reference numeral 101 denotes a transparent electrode; 102, a hole transport layer; 103, a light emitting layer (of R, G, or B); 104, an electron transport layer; and 105, a metal electrode serving also as a total reflection mirror. In FIGS. 1A and 1B, m is a natural number and is used when indicating m times or (m+1) times larger than a resonance wavelength for each R, G, or B.

In this case, difference in refractive index between the transparent electrode 101 and the outside of the organic light emitting device is largest, and hence an interface therebetween exhibits the highest effect as a translucent reflecting surface. Further, in the CIE UV chromaticity diagram (1976), a red range is referred to as reddish orange or red, a green range is referred to as bluish green, green, or yellowish green, and a blue range is referred to as purplish blue, blue, or greenish blue, in most cases.

In a case where a resonator structure is used as in this embodiment, when an emission spectrum obtained without using a resonator structure contains a representative wavelength for each color (620 nm for R, 520 nm for G, or 450 nm for B) as a component, the organic light emitting device can be used in an RGB display device without problems. Note that, when the emission spectrum obtained without using the resonator structure has about a half a peak emission intensity for each color in the representative wavelength for R, G, or B, an efficient device is structured. Further, in view of the fact that a half-width of the emission spectrum of the organic light emitting device is about 10% of a peak wavelength thereof in some cases, when the peak wavelength of the emission spectrum obtained without using the resonator structure falls within a range of about ±5% of the representative wavelength for R, G, or B, an efficient device is structured.

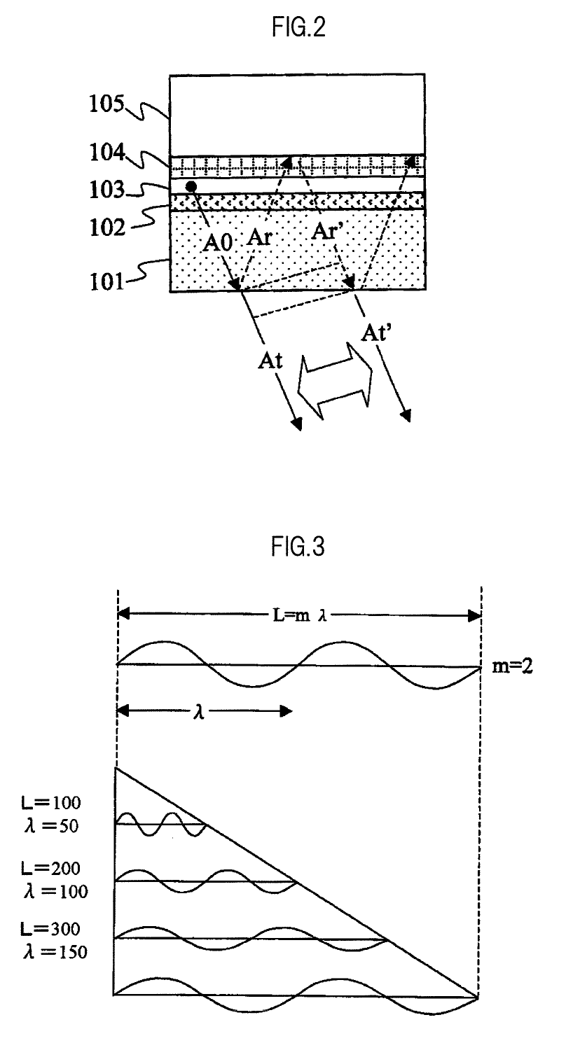

FIG. 2 is an explanatory view of light propagation and interference generation in the organic light emitting device. In FIG. 2, on the translucent reflecting surface serving as an outer surface of the transparent electrode 101 which is provided uppermost in the organic light emitting device, light A0 reaching the translucent reflecting surface from the inside of the device is, owing to a translucent reflecting function thereof, separated into a transmission component At output from the transparent electrode 101 to the outside of the device, and a reflection component Ar reflected inside the device.

After being reflected on a reflecting surface of the total reflection mirror 105 which is present in a back surface of the device, the reflection component Ar reaches the translucent reflecting surface again as a reflection component Ar′, and then is transmitted, as a transmission component At′, from the transparent electrode 101 to the outside of the device.

The transmission components At and At′ are obtained by separating the same origin light A0 into a plurality of components, and hence the transmission components At and At′ are highly coherent with each other, resulting in causing interference (self-interference) at high efficiency. However, because the transmission components At′ has been reflected on the translucent reflecting surface and has traveled to and fro inside the device, the transmission component At′ has a delayed wavelength phase, compared with the transmission component At. Accordingly, a condition of constructive interference is that a delayed phase amount is natural number times as large as a wavelength. When a wavelength satisfies this condition, a wave surface of wavelengths are made in-phase, with the result that the transmission components At and At′ interfere constructively. When a wavelength does not satisfy this condition, interference occurs weakly.

When a path as described above, in which a phase of the transmission component At′ is delayed with respect to the transmission component At, that is, a propagation path of the light A0 from the translucent reflecting surface serving as the outer surface of the transparent electrode 101 to the reflecting surface of the total reflection mirror 105 is assumed as a total resonator length L, the total resonator length L is set to m times larger than a resonance wavelength λ of the light A0, whereby wave surfaces of light to be output are made in-phase and oscillations interfere constructively.

In other words, as illustrated in FIG. 3, “the total resonator length L=mλ” is set. FIG. 3 is a relationship diagram between the total resonator length L and the resonance wavelength λ, which shows a case of m=2.

In an organic light emitting device in which an organic thin film is used for light emission, a total resonator length L is obtained by adding an optical path length, an amount of a phase shift owing to an interface reflection (on a transparent electrode 101 side and a total reflection mirror 105 side), and an offset length of the phase shift generated owing to interface charges which are accumulated in the interface. The optical path length is a sum of values which are obtained by multiplying refractive indexes of layers between reflection mirrors which generate resonance by thicknesses of the layers and doubling (corresponding to-and-fro) the resultant. For example, refer to J. M. Bennet, J. Opt. Soc. Am, 54, (1964)612. One of the constituents of the total resonator length L, that is, the optical path length (sum Σ2nᵢdᵢ of a product of a length dᵢ and a refractive index nᵢ, i is layer number) of the layers between the reflection mirrors, is changed, whereby the total resonator length L can be changed.

In this case, the following equation is satisfied:

L=Σ2nᵢdᵢ+Δ=mλ

Here, Δ is a value obtained by adding the amount of the phase shift owing to the interface reflection and the offset length of the phase shift generated owing to interface charges which are accumulated in the interface.

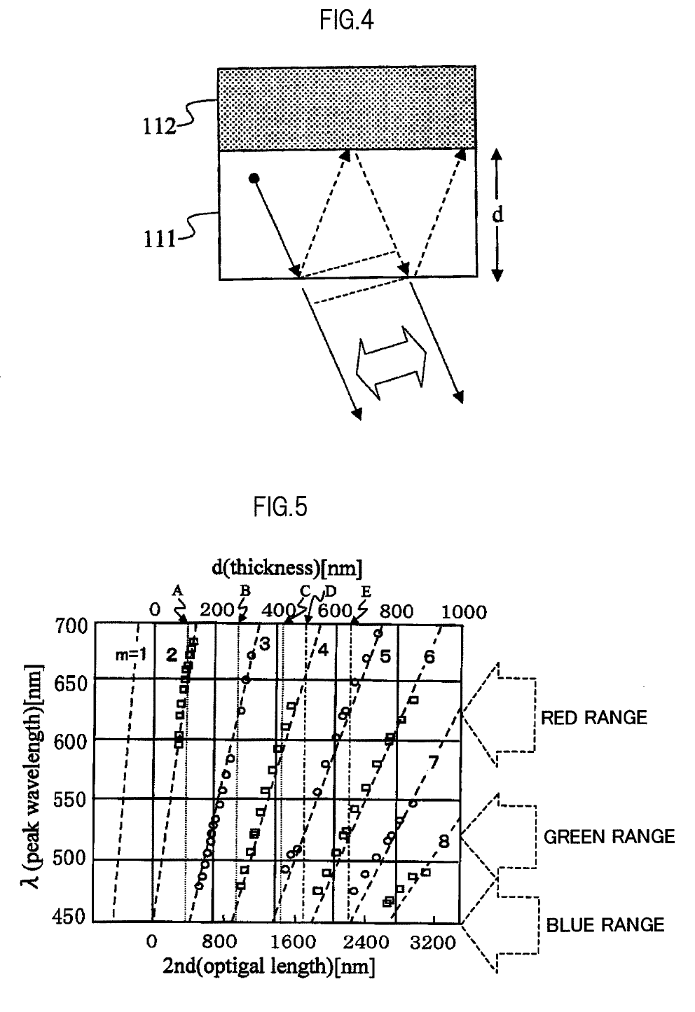

FIG. 4 is a schematic view of an organic light emitting device for determining resonance characteristics. In FIG. 4, the organic light emitting device includes an organic light emitting material (aluminum chelate) 111 and an Ag—Mg reflecting film 112. Note that, when dielectric laminated films are formed outside the aluminum chelate 111 in an order of low refractive index, high refractive index, low refractive index, and high refractive index to have a ¼ optical thickness of a desired wavelength (for example, 520 nm of a spectrum peak wavelength), an amplitude of resonance increases because of an increase in reflection ratio, but wavelength characteristics of the resonance hardly changes.

In this case, samples having a variable thickness d of the aluminum chelate 111 are prepared. FIG. 5 illustrates the wavelength λ having resonance which has been actually observed by optically stimulated luminescence is plotted with respect to an optical path length 2nd. For example, refer to T. Nakayama et al., Extended Abstracts to EL Workshop 98, P. 44.

FIG. 5 is a graph illustrating a relationship among the thickness d, the optical path length 2nd, and a resonance peak wavelength λ. FIG. 5 illustrates a generation point (nm) of the resonance peak wavelength λ depending on the thickness d and the optical path length 2nd. A gradient plotted with a square or a circle illustrated in FIG. 5 becomes an inverse number of m, and a value of m at that time is indicated by a dotted line of FIG. 5. Specifically, λ=(1/m) (2nd+A), and the cases where m corresponds to 1 to 8 are indicated by dotted lines.

The preparation of the graph enables the design of devices having peaks in a plurality of emission colors with respect to individual device structures, and both the simplification of a manufacturing process and the optimization of the structure of device layers in an electrical design can be achieved. In the following description, a thickness which is used for an actual device is obtained from the results of FIG. 5.

In FIG. 5, it is found that the thickness d which has a resonance peak simultaneously in the red range and the blue range is 110 nm, 280 nm, or 420 nm. Specifically, in the case where the thickness d is 110 nm, red has a peak when m=2, and blue has a peak when m=3. In the case where the thickness d is 280 nm, which corresponds to B indicated in FIG. 5, red has a peak when m=3, and blue has a peak when m=4. In the case where the thickness d is 420 nm, which corresponds to C indicated in FIG. 5, red has a peak when m=4, and blue has a peak when m=5.

Here, a refractive index n of the aluminum chelate (ALQ) is 1.7. Therefore, optical path lengths nd of those thicknesses are 187 nm, 476 nm, and 714 nm, respectively, and the total resonator lengths L thereof are 1,010 nm, 1,180 nm, and 1,320 nm, respectively. Those lengths can be actually used in a case where main components are held in regions separated into a red-based area, a green-based area, and a blue-based area in the UV or XY chromaticity diagram. In this case, when the lengths fall within the range of ±5% above and below the above-mentioned lengths in terms of wavelength, respectively, the requirement is satisfied. The range similarly applies to the following description.

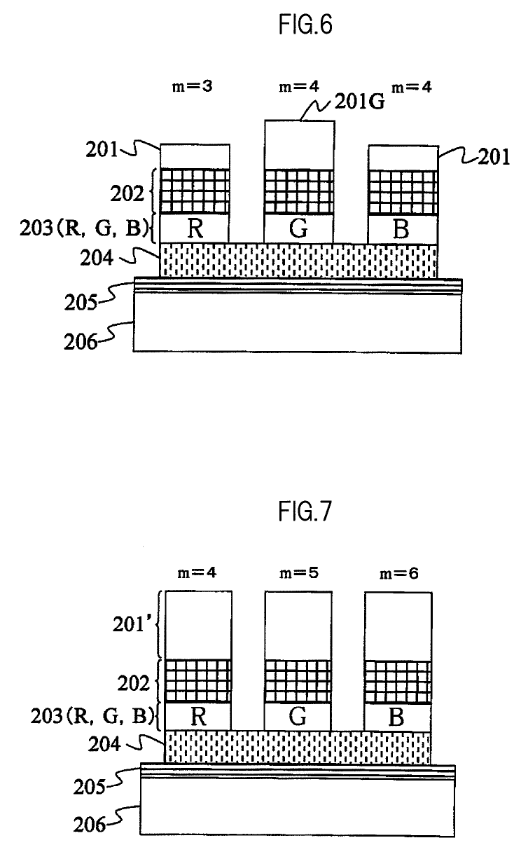

FIG. 6 illustrates an example of a full-color display panel in which a thickness of 280 nm is employed and R, G, and B pixels are arranged. In this case, red is m=3, blue is m=4, and from FIG. 5, green is m=4.

In FIG. 6, reference numeral 201 denotes transparent electrodes (indium tin oxide (ITO) (thickness of 160 nm)) for red and blue pixels; 201G, a transparent electrode for a green pixel (ITO (210 nm)); 202, a hole injection layer (α-NPD (40 nm)); 203R, a red light emitting layer (ALQ: 5% of DCM (20 nm)); 203G, a green light emitting layer (ALQ: 5% of Ir (ppy) 3 (20 nm)); 203B, a blue light emitting layer (ALQ: 20% of distyrylarylene (20 nm)); 204, an electron transport layer (ALQ (40 nm)); 205, a metal electrode serving also as a total reflection mirror (Ag—Mg (100 nm)); and 206, a substrate (glass of 0.7 mm). Here, refractive indexes of the organic films 202, 203, and 204 are about 1.7, and a refractive index of the ITO 201 is about 1.9.

In FIG. 6, the transparent electrode for a green pixel 201G is made thicker than the other electrodes, whereby resonance is obtained in the green pixel. In contrast, when the transparent electrode for a green pixel 201G is made thinner to be 110 nm, resonance is also obtained in the green pixel. In other words, in this case, with reference to FIG. 5, m is changed from 4 to 3.

Further, from FIG. 5, it is found that the thickness d which has a resonance peak simultaneously in the red range, the green range, and the blue range is 490 nm and 660 nm. Specifically, in the case where the thickness d is 490 nm, red has a peak when m=4, green has a peak when m=5, and blue has a peak when m=6. In the case where the thickness d is 660 nm, red has a peak when m=5, green has a peak when m=6, and blue has a peak when m=7.

In this case, the refractive index n of the aluminum chelate (ALQ) is 1.7. Therefore, the optical path lengths nd of those thicknesses are 833 nm and 1,122 nm, respectively, and the total resonator lengths L are 1,390 nm and 2,122 nm, respectively.

FIG. 7 illustrates an example of a full-color display panel in which, with the use of D indicated in FIG. 5, a thickness of 490 nm is employed and R, G, and B pixels are arranged. In this case, red is m=4, green is m=5, and blue is m=6. FIG. 7 is different from FIG. 6 in a transparent electrode 201′ (ITO (350 nm)).

In this embodiment, in order to make the total resonator lengths of the pixels longer, a method involving making the transparent electrode thicker is employed. However, in addition to the method, there are provided a method involving inserting a hole transport film with low resistance (organic film or inorganic film such as molybdenum oxide) between the transparent electrode and the hole injection layer, and a method involving making a thickness of the light emitting layer thicker in an application in which performance reduction of the device is permissible.

Note that the substrate 206 exists outside the resonator structure (between the reflecting surface and the translucent reflecting surface) and thus does not affect the resonator structure. Accordingly, in a case where the light emission is extracted from the transparent electrode 201 side, the substrate 206 is freely selected from inorganic materials and organic materials, and is unnecessary to be transparent. Further, in a case where the substrate 206 is arranged on an outer surface of the transparent electrode 201, the light emission is to be extracted from the substrate 206 side. Thus, the substrate 206 is necessary to be transparent but, as long as being transparent, can be freely selected from inorganic materials and organic materials. Unless there are no problems in intensity and process, the substrate 206 can be omitted.

Further, the optical path length required for the total resonator length is constant. However, when a different film is used as a metal layer or a different organic film is used, a phase displacement amount caused by the reflection is varied, whereby the optical path length between the reflection mirrors is varied. In this embodiment, a refractive index of a material which is used for a normal organic light emitting device is in a range of several percent above and below 1.7. Moreover, a phase displacement amount caused by the reflection of the metal film such as Al, Mg, In, or those alloy, which has been actually used for the organic light emitting device, is not largely varied. As a result, in the range for selecting those materials, the variation of the optical path length between the reflection mirrors represents several percent of the range, which is small.

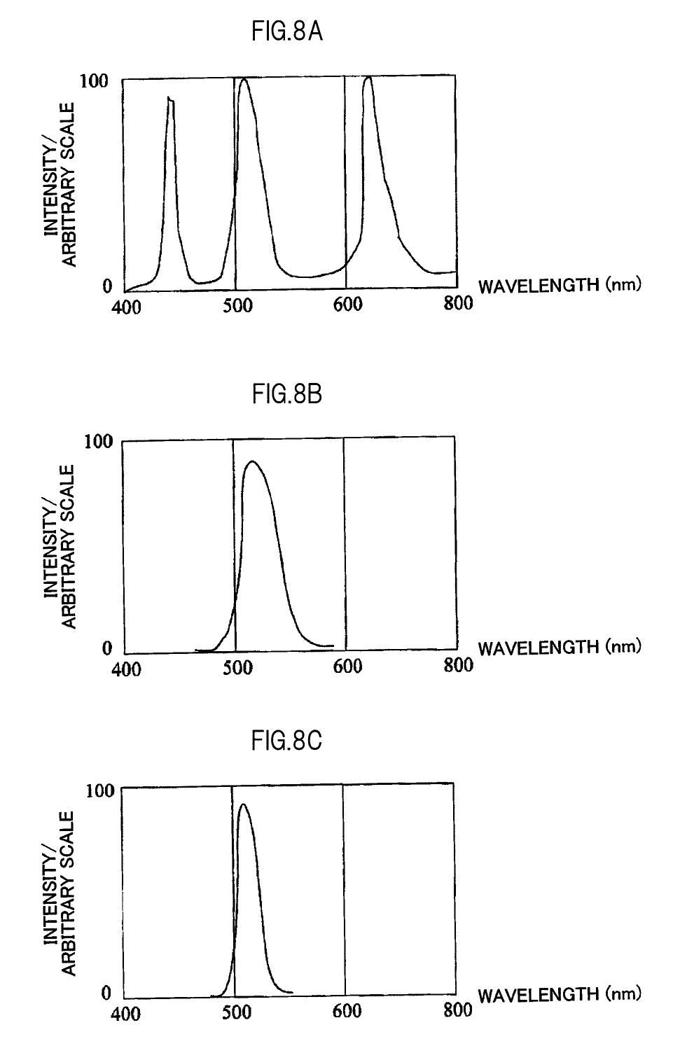

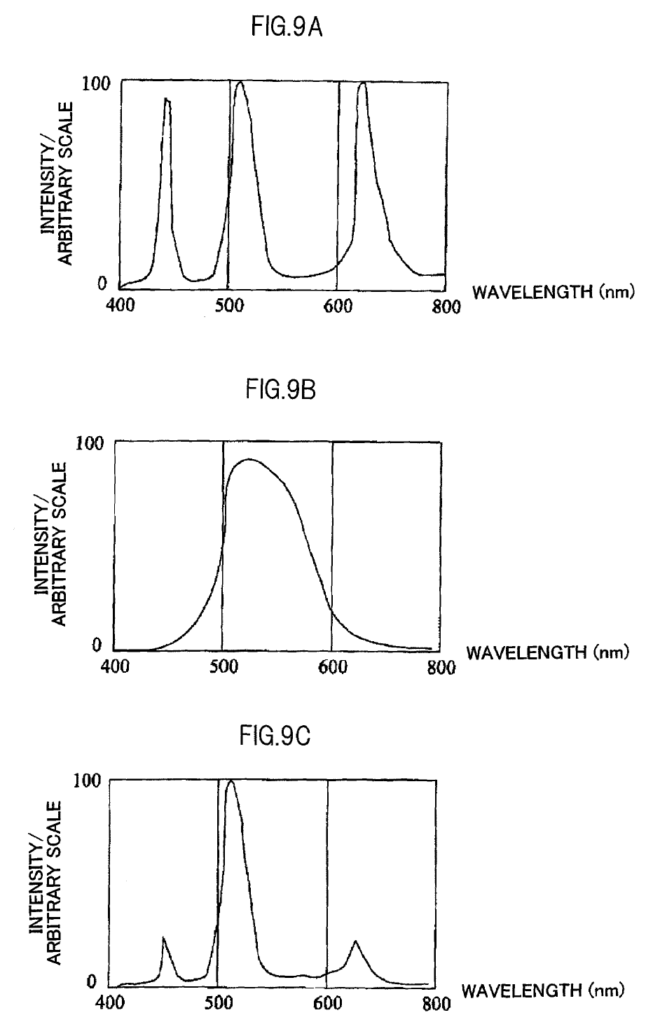

FIGS. 8A to 8C and 9A to 9C are for describing wavelength characteristics of the resonator structure simultaneously having resonance peaks in the red range, the green range, and the blue range illustrated in FIG. 7, with the green range being used as a comparative example.

FIG. 8A is a characteristic diagram of the wavelengths of the resonator structure illustrated in FIG. 7. FIG. 8B is a wavelength characteristic diagram for green in a case where the resonator structure is not employed and an emission spectrum of green has a wavelength range which is sufficiently narrow enough not to extend to resonance peak regions of the other colors. FIG. 8C is a wavelength characteristic diagram for green, which is obtained when the wavelength of green is generated in the resonator structure.

In the case of the resonator structure simultaneously having resonance peaks in the red range, the green range, and the blue range as illustrated in FIG. 8A, it is desirable to use a light emitting layer having such a relatively narrow wavelength range that the emission spectrum without the resonator structure does not contain a component that is shared by the resonance peaks of the other colors, as illustrated in FIG. 8B, and the wavelength characteristic illustrated in FIG. 8C is obtained owing to the resonator structure. In FIGS. 8B and 8C, only the wavelength characteristic of green is illustrated as a representative example, but the same applies to red and blue.

FIG. 9A is a characteristic diagram of the wavelengths of the resonator structure illustrated in FIG. 7. FIG. 9B is a wavelength characteristic diagram for green in a case where the resonator structure is not employed and an emission spectrum of green has a wavelength range which is wide enough to extend to resonance peak regions of the other colors. FIG. 9C is a wavelength characteristic diagram for green, which is obtained when the wavelength of green is generated in the resonator structure.

In the case of the resonator structure simultaneously having resonance peaks in the red range, the green range, and the blue range as illustrated in FIG. 9A, it is desirable to use a light emitting layer having such a relatively narrow wavelength range that the emission spectrum without the resonator structure does not contain a component that is shared by the resonance peaks of the other colors, as illustrated in FIG. 8B. However, as illustrated in FIG. 9B, even in a case where the emission spectrum without the resonator structure contains a component of the other colors, with respect to an application in which only the effect of improving extraction efficiency needs to be achieved and improvement in color purity by using the resonator structure is not so important, a wavelength characteristic illustrated in FIG. 9C, which is obtained by the resonator structure, can be used. In FIGS. 9B and 9C, only the wavelength characteristic of green is illustrated as a representative example, but the same applies to red and blue.

As described above, the results of FIG. 5 depend on the device structure of the organic light emitting device. For example, in a case where dielectric laminated films are formed outside the organic film 111 illustrated in FIG. 4 in an order of high refractive index, low refractive index, high refractive index, and low refractive index to have an optical thickness of a ¼ wavelength, a phase shift of an amount of ½ wavelength is generated due to the reflection. Accordingly, the wavelength characteristic of the resonance is shifted by the amount.

Specifically, the optical path lengths between the reflection mirrors of a device in which resonator lengths for red and blue are the same are 323 nm and 595 nm. The optical path lengths between the reflection mirrors of a device in which resonator lengths for red, green, and blue are the same are 680 nm, 935 nm, and 1,224 nm.

There are cases where the degree of the wavelength dependency on refractive indexes of the respective layers becomes large and cannot be disregarded, and where, in an actual device, the wavelength dependency becomes more complicated due to contribution of a plurality of the translucent reflecting surfaces. For that reason, in the respective structures, the graph of FIG. 5 is experimentally prepared and after that, a thickness for obtaining resonance peaks in a plurality of the light emitting regions is derived, which is the most optimum method.

After the total resonator length L is set to m times larger than a wavelength of a red range and to m+1 times larger than a wavelength of a blue range, in order to improve chromaticity, a thickness or the like of the light emitting layer may be finely adjusted by about several percent. In this case as well, device characteristics which are much more excellent than a case of multiplying the respective wavelengths by m.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic light emitting device, comprising:
resonators for respective three colors of a red range, a green range, and a blue range; and
a plurality of layers, wherein:
when an optical path length which is a sum of values each obtained by multiplying a refractive index nᵢ of each layer i of the plurality of layers by a thickness dᵢ thereof and doubling a resultant is denoted by Σ2nᵢdᵢ, a length obtained by adding an amount of a phase shift owing to an interface reflection and an offset length is denoted by Δ, a natural number is denoted by m, and a resonance wavelength is denoted by Δ,
a total resonator length L of the organic light emitting device is set to L=Σ2nᵢdᵢ+Δ=mλ; and
in the resonator having the red range that emits light, a total resonator length thereof is m times larger than a wavelength λ_{R} of the red range, and in the resonator having the blue range that emits light, a total resonator length thereof is (m+1) times larger than a wavelength λ_{B} of the blue range.

2. An organic light emitting device according to claim 1, wherein, in the resonator having the green range that emits light, the total resonator length L thereof is one of increased and decreased, and a resonance condition corresponding to one of the resonator having the blue range and the resonator having the red range is applied to the resonator having the green range to be used.

3. An organic light emitting device, comprising:
resonators for respective three colors of a red range, a green range, and a blue range; and
a plurality of layers, wherein:
when an optical path length which is a sum of values each obtained by multiplying a refractive index nᵢ of each layer i of the plurality of layers of the organic light emitting device by a thickness dᵢ thereof and doubling a resultant is denoted by Σ2nᵢdᵢ, a length obtained by adding an amount of a phase shift owing to an interface reflection and an offset length is denoted by Δ, a natural number is denoted by m, and a resonance wavelength is denoted by Δ,
a total resonator length L of the organic light emitting device is set to L=Σ2nᵢdᵢ+Δ=mλ; and
in the resonator having the red range that emits light, a total resonator length thereof is m times larger than a wavelength λ_{R} of the red range, in the resonator having the green range that emits light, a total resonator length thereof is (m+1) times larger than a wavelength λ_{G} of the green range, and in the resonator having the blue range that emits light, a total resonator length thereof is (m+2) times larger than a wavelength λ_{B} of the blue range.

4. An organic light emitting device according to claim 1, wherein a light emission of the red range and a light emission of the blue range simultaneously satisfy a resonance condition in which each of the light emissions of the colors is in phase.

5. An organic light emitting device according to claim 4, wherein the total resonator length L falls within a range of ±5% of one of 1,010 nm, 1,180 nm, and 1,320 nm.

6. An organic light emitting device according to claim 4, wherein:
no phase shift of a ½ wavelength occurs owing to a mirror surface reflection on both reflection mirrors of each of the resonators; and
an optical path length between the reflection mirrors falls within a range of ±5% of one of 187 nm, 476 nm, and 714 nm.

7. An organic light emitting device according to claim 4, wherein:
a phase shift of a ½ wavelength occurs owing only to a mirror surface reflection on one of reflection mirrors of each of the resonators; and
an optical path length between the reflection mirrors falls within a range of ±5% of one of 323 nm and 595 nm.

8. An organic light emitting device according to claim 3, wherein a light emission of the red range, a light emission of the green range, and a light emission of the blue range simultaneously satisfy a resonance condition.

9. An organic light emitting device according to claim 8, wherein the total resonator length L falls within a range of ±5% of one of 1,390 nm and 2,122 nm.

10. An organic light emitting device according to claim 8, wherein:
no phase shift of a ½ wavelength occurs owing to a mirror surface reflection on both reflection mirrors of each of the resonators; and
an optical path length between the reflection mirrors falls within a range of ±5% of one of 833 nm and 1,122 nm.

11. An organic light emitting device according to claim 8, wherein:
a phase shift of a ½ wavelength occurs owing only to in a mirror surface reflection on one of reflection mirrors of each of the resonators; and
an optical path length between the reflection mirrors falls within a range of ±5% of one of 680 nm, 935 nm, and 1,224 nm.
